(19) United States
(12) Patent Application Publication
(10) Pub. No.: US 2008/0122427 A1
(43) Pub. Date: May 29, 2008

(54) Device and Method for Measuring a Phase Deviation

(76) Inventor: Christoph Wagner, Linz (AT)

Correspondence Address: SLATER & MATSIL LLP, 17950 PRESTON ROAD, SUITE 1000, DALLAS, TX, 75252, US

(21) Appl. No.: 11/774,290

(22) Filed: Jul. 6, 2007

(30) Foreign Application Priority Data
Jul. 6, 2006 (DE) 10 2006 031 351.8

(51) Int. Cl. G01R 13/00

(52) U.S. Cl. 324/76.83

(57) ABSTRACT

A device for measuring a phase deviation has a sampler having a first input for a periodic measurement signal having a steady-state or a varying frequency, a second input for a reference signal replicating an idealized phase trajectory of the periodic measurement signal, and an output for a sample value of the reference signal sampled by use of the periodic measurement signal. A reference signal generator having an output coupled to the second input of the sampler is provided. Further, provision is made for a phase deviation identifier having an input coupled to the output of the sampler.

This application claims priority from German Patent Application No. 10 2006 031 351.8, which was filed on Jul. 6, 2006, and is incorporated herein in its entirety by reference.

### TECHNICAL FIELD

The present invention refers to a method and a device for measuring a phase deviation, or difference, in particular to a device for measuring a linearity of a frequency deflection, such as is used in automotive radar systems, for example.

### BACKGROUND

In automotive engineering, so-called FMCW radar systems (FMCW=frequency modulated continuous wave) are used in driver assistance systems, for example, to reduce the number of car accidents, among other things. In a FMCW radar system, a linearly frequency-modulated high-frequency signal (HF signal) is used. Thus, a time-dependent transmitting frequency f_{HF}(t) of the HF signal linearly increases in a time interval Δt by an amount Δf_{HF}, for example, or is deflected by Δf_{HF}. This frequency deflection is referred to as a so-called frequency sweep. Through a run time t_{d} during a signal propagation of the HF signal to a reflector, the transmitting frequency of the HF signal changes in the meantime, to f_{HF}(t+t_{d}) due to the frequency deflection, so that one can obtain with a mixer a low-frequency signal with a frequency f_{NF}(t+t_{d})=f_{HF}(t+t_{d})−f_{HF}(t) from the difference between the current transmitting frequency f_{HF}(t+t_{d}) and the receiving frequency f_{HF}(t) reflected by the reflector. The frequency f_{NF}(t+t_{d}) is proportional to a reflector distance d. Thus, in FMCW radar systems, the run time t_{d} is converted to the frequency f_{NF}(t+t_{d}). If the frequency sweep is linear, the frequency f_{NF}(t+t_{d}) of the low-frequency mix signals will remain constant during the sweep operation.

In FMCW radar systems, the linearity properties of the transmitted frequency sweep are of great importance. Nowadays, typical frequency sweep bandwidths Δf_{HF} range from several hundred MHz to some GHz. For automotive radar applications, for example, a frequency band at 77 GHz is reserved. In comparison to a center frequency and the bandwidth Δf_{HF} of the frequency sweep, a non-linearity of the frequency sweep is very small and, for this reason, difficult to measure.

### SUMMARY OF THE INVENTION

According to one embodiment, the present invention includes a device for measuring a phase deviation with a sampler having a first input for a periodic measurement signal comprising a steady-state or a variable frequency, a second input for a reference signal replicating an idealized phase trajectory of the measurement signal, and an output for a sample value of the reference signal sampled by use of the measurement signal, a reference signal generator with an output coupled to the second input of the sampler, and a phase deviation identifier with an input coupled to the output of the sampler.

Embodiments of the present invention further provide a method for measuring a phase deviation comprising a step of providing a periodic measurement signal comprising a steady-state or a variable frequency, a step of providing a reference signal replicating an idealized phase trajectory of the measurement signal, a step of sampling the reference signal by use of the measurement signal for generating a sample value of the reference signal, and a step of identifying the phase deviation of the measurement signal from the reference signal of the sample value of the reference signal.

### BRIEF DESCRIPTION OF THE DRAWINGS

In the following, embodiments of the present invention will be explained in detail with reference to the accompanying drawings, wherein:

FIG. 1 shows a conventional arrangement for a linearity measurement of a frequency sweep with a frequency converter and a digital storage oscilloscope;

FIG. 2 shows a diagrammatic block diagram of a conventional arrangement for linearity measurement of a frequency sweep with a phase frequency detector;

FIG. 3 shows a diagrammatic block diagram of a device for measuring a phase deviation according to an embodiment of the present invention;

FIG. 4a shows a diagrammatic illustration of a frequency sweep plotted versus time;

FIG. 4b shows a diagrammatic illustration of a measurement signal with variable frequency;

FIG. 4c shows a phase diagram for explaining of the measurement principle of the phase deviation according to an embodiment of the present invention; and

FIG. 5 shows a diagrammatic block diagram of a device for measuring a phase deviation according to an embodiment of the present invention with external wiring for a frequency conversion of the measurement signal.

### DETAILED DESCRIPTION OF ILLUSTRATIVE EMBODIMENTS

It should be noted that with respect to the following description, identical functional elements or functional elements operating in the same way have identical reference numbers in the different embodiments, and, thus, the descriptions of these functional elements in the different embodiments illustrated in the following are interchangeable.

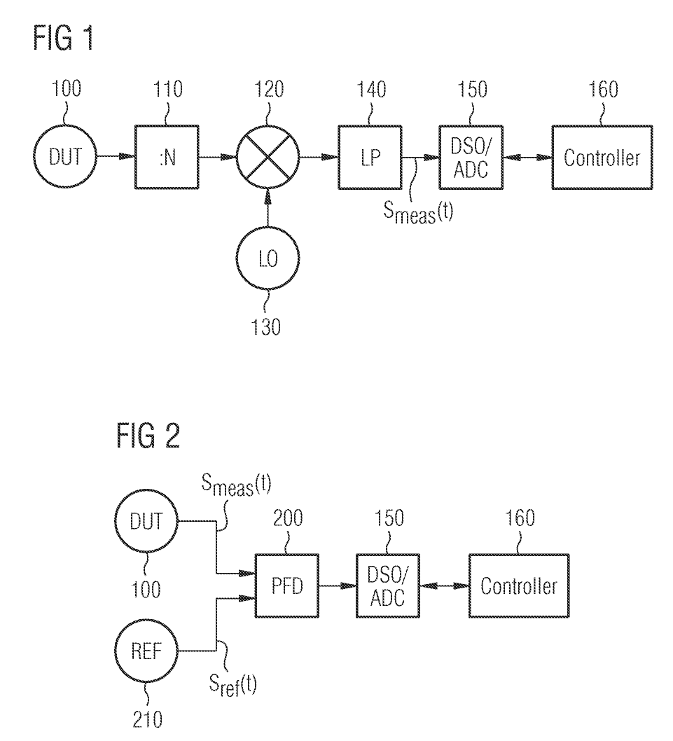

Known systems for linearity measurement of a frequency sweep are based on the use of so-called digital storage oscilloscopes (DSO). Such a system is illustrated by way of example in FIG. 1.

FIG. 1 shows a signal source 100 coupled to a frequency divider 110 on the output side. The output of the frequency divider 110 forms a first input of a mixer 120. An output of a local oscillator 130 forms a second input of the mixer 120. An output of the mixer 120 is coupled to a low-pass filter 140. An output of the low-pass filter 140 forms an input of a digital storage oscilloscope 150 coupled to a controller means 160.

A simple and known approach to linearity measurement of a frequency sweep is to down-convert a time-dependent frequency f_{HF}(t) of the output signal s_{HF}(t) of the signal source 100 with the frequency divider 110 by a factor N, for example. The measurement signal down-converted in its frequency by the factor N and comprising an at least approximately linear frequency sweep, i.e., a linear frequency deflection, is further down-converted by means of the mixer 120 and the local oscillator 130 comprising a frequency f_{LO}, and is sampled with the digital storage oscilloscope 150 after low-pass filtration with the low-pass filter 140. Thus, the mixed and low-pass filtered measurement signal sₘₑₐₛ(t) comprises a frequency fₘₑₐₛ(t)=f_{HF}(t)/N−f_{LO}.

A phase information may now be determined from the so-called analytical signal of the measurement signal sₘₑₐₛ(t), for example. One obtains the analytical signal by adding an imaginary portion resulting from the Hilbert-transform of the real measurement signal sₘₑₐₙₛ(t) to the measurement signal sₘₑₐₛ(t). To calculate a phase error of the analytical signal of the measurement signal, a mathematically generated ideal phase trajectory φ_{ref}(t) of the analytical signal, for example, is adapted to the measured data, and the different signal of the ideal phase trajectory φ_{ref}(t) is compared with the phase trajectory φₘₑₐₛ(t) of the measurement signal.

Instead of the digital storage oscilloscope, an analog-to-digital converter, for example, may also be used. In the end, however, a complex and expensive signal management system still remains necessary to obtain the result of the linearity measurement of the frequency sweep.

The use of a phase frequency detector is a further common approach to linearity measurement of a frequency sweep. A diagrammatic block diagram of such a measurement system is shown in FIG. 2.

FIG. 2 shows a measurement signal source 100 coupled to a first input of a phase frequency detector 200. A reference signal source 210 is coupled to a second input of the phase frequency detector 200. An output of the phase frequency detector 200 is wired to a digital storage oscilloscope, or an analog-to-digital converter, 150 controlled by a controller means 160.

In the measurement system shown in FIG. 2, the reference signal source 210 generates a reference signal s_{ref}(t) having an idealized frequency trajectory f_{ref}(t), or phase trajectory φ_{ref}(t), of the measurement signal sₘₑₐₛ(t) generated by the measurement signal source 100. The idealized frequency trajectory fret) means a requested, i.e. for example absolutely linear, frequency trajectory. On the basis of the measurement signal sₘₑₐₛ(t) and the reference signal s_{ref}(t), the phase frequency detector 200 identifies a signal, such as a current or a voltage, for example, proportional to a phase difference φ_{diff}(t) of both of the signals, which is digitalized by means of the digital storage oscilloscope, or the analog-to-digital converter, 150, and is then further processed.

As in the measurement system described in the foregoing on the basis of FIG. 1, this implementation has the disadvantage that the realization is very expensive with respect to hardware and software.

Finally, the principle of FMCW radar systems itself may also be used for linearity measurement of a frequency sweep. For this purpose, the measurement signal sₘₑₐₛ(t) is mixed with the frequency ramp resulting from the frequency deflection, such as a time-shifted version sₘₑₐₛ(t+t_{d}) thereof, for example. For this purpose, a coaxial cable may be used, for example, as a delay line with a known electrical length and a mixer mixing both of the time-shifted signals sₘₑₐₛ(t) and sₘₑₐₛ(t+t_{d}). In an ideal linear frequency sweep, the low-frequency signal resulting at the mixer output comprises only a single component at a frequency f_{NF}=fₘₑₐₛ(t+t_{d})−fₘₑₐₛ(t) corresponding to the time delay, whereas in the case of a non-linearity of the frequency sweep, the spectrum of the resulting signal is broadened. Here, too, a sampling must be performed using an analog-to-digital converter, and the result is to be evaluated by means of software in a PC, for example.

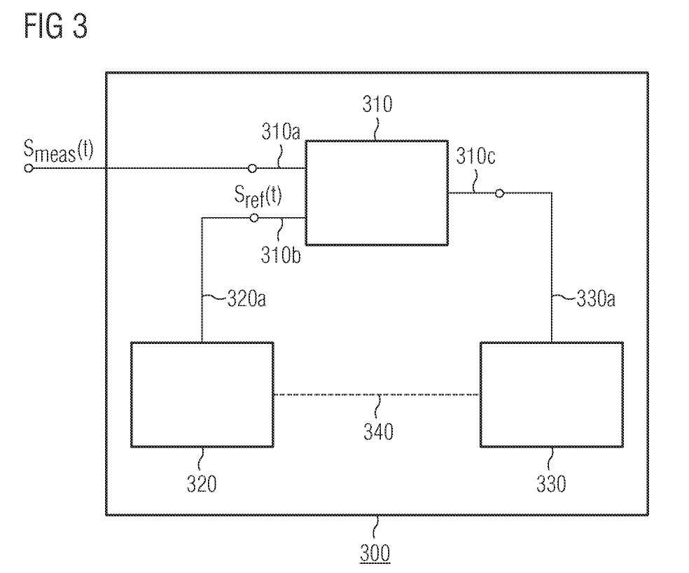

After known systems for linearity measurement of a frequency sweep have been described in the foregoing on the basis of FIG. 1 and FIG. 2, the concept for linearity measurement of a frequency sweep according to an embodiment of the present invention is to be illustrated in more detail on the basis of FIG. 3 to FIG. 5.

A measurement method according to one embodiment of the present invention is based on the principle of a direct digital synthesizer (DDS). A direct digital synthesizer numerically calculates in a clock cycle of the duration T_{clk} a phase φ of a 2π periodic signal using a so-called phase accumulator. A so-called tuning word forms a phase increment Δφ of the phase accumulator. For example, in a clock cycle n, the phase φ(n·T_{clk}) of the phase accumulator is increased by the phase increment Δφ, thus, φ(n·T_{clk})=φ((n−1)T_{clk})+Δφ. A digital phase word of the phase accumulator consists of a specified number of bits, such as j bits. Each time the phase accumulator overflows, i.e. in a transition from φ(n·T_{clk})=2^{j}−1 to φ((n+1)·T_{clk}), a complete period of the periodic signal is generated. For this reason, the phase increment Δφ of the phase accumulator and a clock frequency f_{clk}=1/T_{clk} of the direct digital synthesizer define an output frequency fₒᵤₜ generated by the direct digital synthesizer. By increasing the tuning word, i.e., the phase increment Δφ, from one clock cycle to the next, a linear frequency sweep may be synthesized, for example.

According to embodiments of the present invention, the output of the digital phase accumulator is sampled at times of zero crossings of the rising signal edge of the periodic measurement signal. In the process, the phase accumulator generates the reference frequency sweep by making available phase values of the reference sweep at a high digital resolution and with a clock rate f_{clk} suitable for the bandwidth of the frequency sweep. Since the phase of the measurement signal at the time of the sampling comprises a value which is a multiple of 2π, the value of the phase accumulator at this sample time represents a measure of a phase deviation of the frequency sweep of the measurement signal from the ideal linear frequency sweep of the reference signal.

FIG. 3 shows a diagrammatic block diagram of a device for measuring a phase deviation according to an embodiment of the present invention.

Device 300 comprises a sampler 310 including a first input 310a, a second input 310b, and an output 310c. Device 300 further includes a reference signal generator 320 with an output 320a coupled to the second input 310b of the sampler 310. Device 300 further includes a phase deviation identifier 330 having an input 330a coupled to the output 310c of the sampler 310. As indicated by the dotted line 340, the phase deviation identifier may be coupled, e.g., to the reference signal generator 320.

Via the input 310a, a periodic measurement signal sₘₑₐₛ(t) that may comprise a steady-state or a variable frequency fₘₑₐₛ(t) is supplied to the sampler 310. A digital reference signal s_{ref}(t) generated by the reference signal generator 320 with a clock frequency f_{clk} and replicating an idealized frequency trajectory f_{ref}(t), or phase trajectory φ_{ref}(t), of the analog periodic measurement signal sₘₑₐₛ(t) present at the input 310a is present at the second input 310b of the sampler 310, i.e. s_{ref}(t)=φ_{ref}(t).

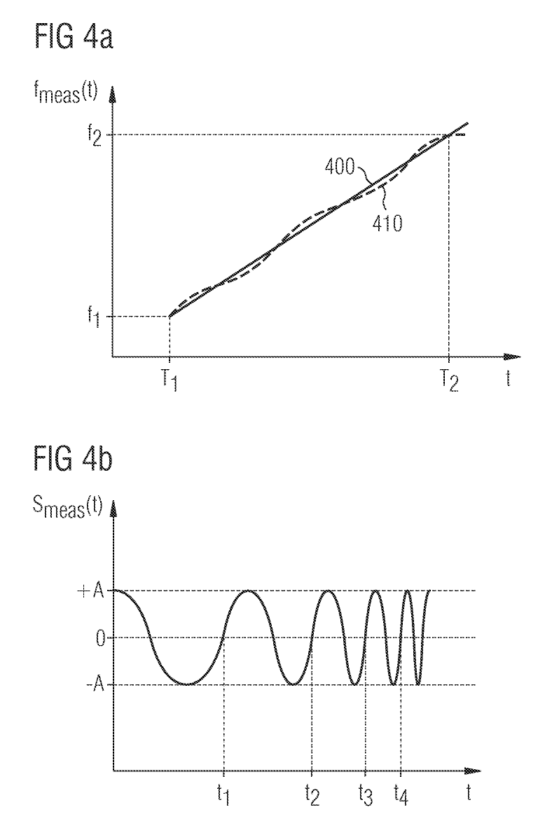

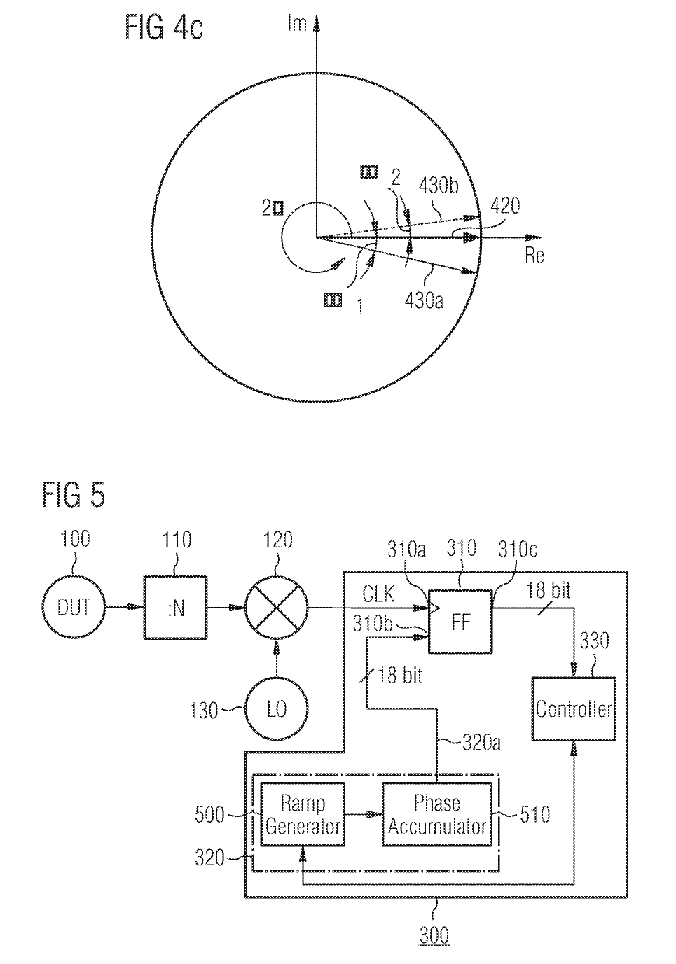

One frequency trajectory fₘₑₐₛ(t), which is possible in principle, of the periodic measurement signal sₘₑₐₛ(t) present at the input 310a of the sampler 310 is shown in FIG. 4a. The graph marked with reference number 400 means an idealized frequency trajectory f_{ref}(t) of the measurement signal sₘₑₐₛ(t), whereas the graph marked with reference number 410 represents a possible real frequency trajectory fₘₑₐₛ(t) of the measurement signal sₘₑₐₛ(t). On the basis of FIG. 4a it should be appreciated that in a linear frequency sweep, a frequency is increased from a frequency f₁ to a frequency f₂ within a period Δt=(T₂−T₁).

For better illustration, this connection is represented yet again in FIG. 4b. FIG. 4b shows a measurement, or an oscillation, signal sₘₑₐₛ(t) whose oscillation frequency continuously increases.

A periodic signal of the form as is shown in FIG. 4b, for example, is present as the measurement signal sₘₑₐₛ(t) at the input 310a of the sampler 310 of the device 300. The times when the sampler 310 samples the reference signal s_{ref}(t) present at the input 310b are marked, by way of example, with t₁ to t₄ in FIG. 4b. According to one embodiment of the present invention, the sampler 310 samples the reference signal s_{ref}(t) within a predetermined range of zero crossings of the rising signal edge of the periodic measurement signal sₘₑₐₛ(t) at the input 310a, as is shown in FIG. 4b. The predetermined range means that sampling is performed exactly at the zero crossing of sₘₑₐₛ(t), for example, or within a range in which the magnitude |sₘₑₐₛ(t)| of the measurement signal comprises a value smaller than 10% of the amplitude of sₘₑₐₛ(t). Thus, the following conditions are at least approximately satisfied at the sample times:

sₘₑₐₛ(t)=0 and (1)

dsₘₑₐₛ(t)/dt>0 (2)

If conditions (1) and (2) are satisfied, the phase φₘₑₐₛ(t) of the periodic measurement signal sₘₑₐₛ(t) comprises a value, which at least approximately corresponds to a multiple of 2π, i.e. φₘₑₐₛ(t)=i*2π(i=0, 1, 2 . . . ). The measurement signal sₘₑₐₛ(t) will typically comprise a frequency response which does not take an ideal linear course, as is indicated in FIG. 4a by the graph with reference number 410.

By the reference signal generator 320, a digital reference signal s_{ref}(t) replicating an idealized linear phase trajectory φ_{ref}(t) of the measurement signal is generated, as is indicated by reference number 400 in FIG. 4a. This reference signal s_{ref}(t) is now sampled by the sampler 310 at those times, for example, when the measurement signal sₘₑₐₛ(t) comprises a zero crossing of the rising signal edge, such as has been described in the foregoing and is indicated in FIG. 4b. Since the sample times comprise a generally non-constant time interval of 1/fₘₑₐₛ(t), the phase of the measurement signal φₘₑₐₛ(t) is a multiple of 2π, the sampled phase value φ_{ref}(t) of the reference signal at these sample times represents a measure of a phase deviation of the measurement signal from the ideal reference frequency sweep. For a better illustration, this connection is depicted in FIG. 4c.

FIG. 4c shows a phase diagram comprising a phase indicator 420 comprising a position corresponding to a phase value according to a multiple of 2π. The phase indicator 420 corresponds to the phase indicator of the measurement signal sₘₑₐₛ(t) at the sample times. FIG. 4c further shows a phase indicator 430a which deviates from the phase indicator 420 by a phase difference Δφ_{,} and a phase indicator 430b which deviates from the phase indicator 420 by a phase difference Δφ₂. The positions of the phase indicators 430a,b correspond to possible phase values of the reference signal φ_{ref}(t) at the sample times.

It is to be understood that in embodiments of the present invention, sample times other than the times of zero crossings of the rising signal edge are also possible. For example, the sampler 310 could sample the reference signal s_{ref}(t) within a predetermined range of zero crossings of the falling signal edge of the periodic measurement signal sₘₑₐₛ(t). The phase φₘₑₐₛ(t) of the periodic measurement signal sₘₑₐₛ(t) would then comprise a value which at least approximately corresponds to an odd-number multiple of π, i.e. φₘₑₐₛ(t)=(2i+1)*π(i=0, 1, 2, . . . ). The sampler 310 could further sample the reference signal s_{ref}(t) generally within a predetermined range of zero crossings of the periodic measurement signal sₘₑₐₛ(t). The phase φₘₑₐₛ(t) of the periodic measurement signal sₘₑₐₛ(t) would then comprise a value which at least approximately corresponds to a multiple of π, i.e. φₘₑₐₛ(t)=i*π(i=0, 1, 2, 3, . . . ).

With the phase deviation identifier 330 shown in FIG. 3, the phase deviation between the measurement signal sₘₑₐₛ(t) and the reference signal s_{ref}(t) may be determined as follows. The phase φₘₑₐₛ(t) of the measurement signal sₘₑₐₛ(t) comprises, at the sample times, a value which corresponds to a multiple of 2π, as is indicated in FIG. 4c by the phase indicator 420. The phase value φ_{ref}(t) of the reference signal of the phase accumulator at the sample times, or at the zero crossings of the rising signal edge of the measurement signal sₘₑₐₛ(t), represents the sampled measurement value

φₛₐₘₚ(t)=φ_{ref}(t)−φₘₑₐₛ(t), (3).

the phase value φₘₑₐₛ(t), related to a period of the measurement signal, comprising at least approximately a value of zero due to the zero crossings, i.e. φₘₑₐₛ(t)=0. The phase deviation φ_{diff}(t) may thus be determined according to

φ_{diff}(t)=φₘₑₐₛ(t)−φ_{ref}(t)=−φₛₐₘₚ(t)=−φ_{ref}(t) (4).

As already described in the foregoing, this value φ_{diff}(t) is sampled at a sample frequency corresponding only to the momentary frequency fₘₑₐₛ(t) of the measurement signal sₘₑₐₛ(t). By contrast, in the concepts described on the basis of FIGS. 1 and 2 a sample frequency corresponding to at least twice the frequency fₘₑₐₛ(t) of the measurement signal sₘₑₐₛ(t) is used.

For most practical applications, this measurement data φ_{diff}(t), which is not uniformly sampled, has to be resampled again at a constant sample rate. However, with suitable signal processing in the phase deviation identifier 330, it is also possible to work with the measurement data φ_{diff}(t), which is non-uniformly sampled. A frequency difference φ_{diff}(t) between the reference signal and the measurement signal sₘₑₐₛ(t) may be determined by a numeric differentiation of the phase measurement data, for example, φ_{diff}(t)=dφ_{diff}(t)/dt.

Embodiments of the present invention may allow a real-time measurement with minimum hardware costs, and thus allow an in-system frequency sweep evaluation and possibly even a sweep linearization.

FIG. 5 shows a diagrammatic block diagram of a device for measuring a phase deviation according to a further embodiment of the present invention comprising external wiring to down-convert a frequency of a measurement signal.

FIG. 5 shows a measurement signal source 100 connected to a frequency divider 110. An output of the frequency divider 110 forms a first input of a mixer 120, and an output of a stable local oscillator 130 forms a second input of the mixer 120. An output of the mixer 120 forms an input 310a of a sampler 310 of the device 300. An output 320a of a reference signal generator 320 is coupled to a second input 310b of the sampler 310. The reference signal generator 320 comprises a phase increment generator 500 coupled to a phase accumulator 510. The output of the phase accumulator forms the output of the reference signal generator 320. The phase increment generator 500 is controlled by a controller 330. An input of the controller 330 is coupled to an output 310c of the sampler 310.

The time-varying frequency f_{HF}(t) of the periodic measurement signal s_{HF}(t) with the sweep bandwidth Δf_{HF} of the measurement signal source 100 is down-converted, by means of the frequency divider 110 and the mixer 120, to a frequency fₘₑₐₛ(t) and a bandwidth Δfₘₑₐₛ that are suitable for conventional digital logic technologies. Further, the measurement signal sₘₑₐₛ(t) is down-converted in its frequency is used as a clock signal for the sampler 310, as described in the foregoing, to sample the momentary values φ_{ref}(t) of the phase accumulator 510 and then to determine therefrom a phase deviation of the measurement signal from the reference signal in accordance with a procedure according to an embodiment of the present invention. The phase increment generator 500 and the phase accumulator 510 generate the frequency sweep ideally expected by the measurement signal sₘₑₐₛ(t). The measurement signal source 100 may be the transmitter of an automotive radar system, for example. Automotive radar systems work in a frequency band at 77 GHz, for example, and generate frequency sweeps of a bandwidth Δf_{HF} of approximately 1 GHz. Since a frequency f_{ref} generated by a direct digital synthesizer is typically within a range of several hundred MHz to 1 GHz, the original measurement signal s_{HF}(t) of the measurement signal source 100 is down-converted in its frequency. The clock rate f_{clk} of the phase accumulator 510 should be large enough to cover the necessary signal bandwidth of the down-converted measurement signal sₘₑₐₛ(t). If the output of the phase accumulator 510 comprises a word width of j bits, a time-varying frequency of the reference signal may be represented by means of a time-varying phase increment Δφ_{ref}(t) according to

$${f}_{ref} ( t ) = \frac{Δ {ϕ}_{ref} ( t ) \cdot {f}_{clk}}{{2}^{j}}$$

In this context, the time response of the phase increment Δφ_{ref}(t) of the phase increment generator 500 is controlled by the controller 330, for example.

Thus, embodiments of the present invention have the advantage that in-system measurements of a linearity of a frequency sweep over large bandwidths are allowed with few hardware requirements. Thus, embodiments of the present invention may allow real-time measurement with minimum hardware expenditure, and thus, an in-system frequency sweep evaluation and possibly even a sweep linearization.

In particular, it should be understood that depending on the circumstances, the inventive scheme may also be implemented in to software. The implementation may be made on a digital storage medium, in particular a disc or a CD with control signals that can be read out electronically and can co-operate with a programmable computer system so the respective method is carried out. In general, the invention also exists as a computer program product comprising a program code, stored on a machine-readable carrier, to perform the inventive method, when run on a computer. In other words, the invention may be realized as a computer program comprising a program code for performing the method, when the run on a computer.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A device for measuring a phase deviation, the device comprising:
a sampler comprising a first input for a periodic measurement signal comprising a steady-state or a varying frequency, a second input for a reference signal replicating an idealized phase trajectory of the periodic measurement signal, and an output for a sample value of the reference signal sampled by use of the periodic measurement signal;
a reference signal generator comprising an output coupled to the second input of the sampler; and
a phase deviation identifier comprising an input coupled to the output of the sampler.

2. The device according to claim 1, wherein the periodic measurement signal present at the first input of the sampler comprises a linear frequency sweep, or a linearly increasing or falling sweep frequency.

3. The device according to claim 1, wherein the sampler can sample the reference signal within a predetermined range of a zero crossing of a rising or falling signal edge of the periodic measurement signal.

4. The device according to claim 1, wherein the reference signal generator comprises a phase increment generator comprising a phase increment output, and a phase accumulator comprising an input coupled to the phase increment output, and a reference signal output coupled to the second input of the sampler.

5. The device according to claim 1, wherein a clock frequency of the reference signal generator is larger than a highest frequency of the periodic measurement signal.

6. The device according to claim 1, wherein the phase deviation identifier identifies a phase deviation φ_{diff}(t) of a phase φₘₑₐₛ(t) of the periodic measurement signal from a phase φ_{ref}(t) of the reference signal according to:
φ_{diff}(t)=φₘₑₐₛ(t)−φ_{ref}(t),
t corresponding to sample times of the sampler.

7. A device for measuring a phase deviation of a phase of a periodic measurement signal from a phase of a reference signal replicating an idealized phase trajectory of the periodic measurement signal with a linearly varying sweep frequency, the device comprising:
a sampler comprising a first input for the periodic measurement signal, a second input for the reference signal, and an output for a sample value of the reference signal, the sample value of the reference signal being sampled within a predetermined range of a zero crossing of a rising or falling signal edge of the periodic measurement signal;
a phase increment generator comprising a phase increment output;
a phase accumulator comprising a phase increment input coupled to the phase increment output of the phase increment generator, and comprising a reference signal output coupled to the second input of the sampler; and
a phase deviation identifier comprising an input coupled to the output of the sampler.

8. The device according to claim 7, wherein a clock frequency of the phase accumulator is larger than a highest frequency of the periodic measurement signal.

9. The device according to claim 7, wherein the phase deviation identifier identifies a phase deviation φ_{diff}(t) of a phase φₘₑₐₛ(t) of the periodic measurement signal from a phase φ_{ref}(t) of the reference signal according to:
φ_{diff}(t)=φₘₑₐₛ(t)−φ_{ref}(t),
t corresponding to sample times of the sampler.

10. A device for measuring a phase deviation, comprising:
means for providing a periodic measurement signal comprising a steady-state or a varying frequency;
means for providing a reference signal replicating an idealized phase trajectory of the periodic measurement signal;
means for sampling the reference signal by use of the periodic measurement signal for generating a sample value of the reference signal; and
means for identifying, from the sample value of the reference signal, the phase deviation of the periodic measurement signal from the reference signal.

11. The device according to claim 10, wherein the periodic measurement signal provided by the means for providing comprises a linear frequency sweep.

12. The device according to claim 10, wherein the means for sampling samples the reference signal within a predetermined range of a zero crossing of a rising or falling signal edge of the periodic measurement signal.

13. The device according to claim 10, wherein the means for providing a reference signal further comprises a means for providing a phase increment and a means for providing an accumulated phase.

14. The device according to claim 10, wherein a clock frequency of the means for providing the reference signal is larger than the highest frequency of the periodic measurement signal.

15. The device according to claim 10, wherein the means for identifying the phase deviation identifies the phase deviation φ_{diff}(t) of a phase φₘₑₐₛ(t) of the periodic measurement signal from a phase φ_{ref}(t) of the reference signal according to:
φ_{diff}(t)=φₘₑₐₛ(t)−φ_{pref}(t),
t corresponding to sample times of the sampler.

16. A method for measuring a phase deviation, the method comprising:
providing a periodic measurement signal comprising a steady-state or varying frequency;
providing a reference signal replicating an idealized phase trajectory of the periodic measurement signal;
sampling the reference signal using the periodic measurement signal to generate a sample value of the reference signal; and
identifying, from the sample value of the reference signal, the phase deviation of the periodic measurement signal from the reference signal.

17. The method according to claim 16, wherein providing the periodic measurement signal is performed such that the periodic measurement signal comprises a linear frequency sweep, or a linearly increasing or falling sweep frequency.

18. The method according to claim 16, wherein sampling of the reference signal is performed within a predetermined range of a zero crossing of a rising or falling signal edge of the periodic measurement signal.

19. The method according to claim 16, wherein providing the reference signal further comprises providing a phase increment and providing an accumulated phase.

20. The method according to claim 16, wherein providing the reference signal further comprises providing a clock frequency, the clock frequency being larger than a highest frequency of the periodic measurement signal.

21. The method according to claim 16, wherein identifying the phase deviation of the periodic measurement signal is performed such that the phase deviation φ_{diff}(t) of a phase φₘₑₐₛ(t) of the periodic measurement signal from a phase φ_{ref}(t) of the reference signal is identified according to:
φ_{diff}(t)=φₘₑₐₛ(t)−φ_{ref}(t),
t corresponding to sample times of the sampler.

22. A computer program comprising a program code for performing a method for measuring a phase deviation, the method comprising:
providing a periodic measurement signal comprising a steady-state or varying frequency;
providing a reference signal replicating an idealized phase trajectory of the periodic measurement signal;
sampling the reference signal by use of the periodic measurement signal for generating a sample value of the reference signal; and
identifying, from the sample value of the reference signal, the phase deviation of the periodic measurement signal from the reference signal, when the computer program runs on a computer.
